(19) United States
(12) Patent Application Publication
(10) Pub. No.: US 2026/0066929 A1
(43) Pub. Date: Mar. 5, 2026

(54) WIRELESS COMMUNICATION CHIP

(71) Applicant: REALTEK SEMICONDUCTOR CORP., Hsinchu (TW)

(72) Inventors: Yang Chang, Hsinchu (TW); Jon-Jin Chen, Hsinchu (TW); Chia-Jun Chang, Hsinchu (TW)

(73) Assignee: REALTEK SEMICONDUCTOR CORP., Hsinchu (TW)

(21) Appl. No.: 19/316,203

(22) Filed: Sep. 2, 2025

(30) Foreign Application Priority Data
Sep. 3, 2024 (TW) 113133349

(51) Int. Cl. H04B 1/04; H03F 3/19; H04W 4/80; H04W 84/12

(52) U.S. Cl. CPC H04B 1/04; H04W 4/80; H03F 3/19; H03F 2200/451; H04B 2001/0408; H04W 84/12

(57) ABSTRACT

A wireless communication chip includes an amplifier stage, a first radio frequency circuit, and a second radio frequency circuit. The amplifier stage is configured to receive and amplify a radio frequency signal. The first radio frequency circuit includes a mixer, a baseband transconductor, an output stage, and a switch unit. The mixer is configured to receive an oscillation signal and the radio frequency signal from the amplifier stage, and is configured to adjust a frequency of the radio frequency signal based on the oscillation signal. The switch unit is electrically connected between an input terminal of the baseband transconductor and an output terminal of the baseband transconductor. The first radio frequency circuit and the second radio frequency circuit support different wireless transmission technologies, and are jointly coupled to an output terminal of the amplifier stage.

### CROSS-REFERENCE TO RELATED APPLICATION

This non-provisional application claims priority under 35 U.S.C. § 119(a) to patent application No. 113133349 filed in Taiwan, R.O.C. on Sep. 3, 2024, the entire contents of which are hereby incorporated by reference.

### BACKGROUND

### Technical Field

The present disclosure relates to a wireless local area network (WLAN) technology and a Bluetooth (BT) communication technology, and in particular, to a wireless communication chip including a WLAN function and a BT communication function.

### Related Art

With progress of science and technology, wireless communication chips gradually become mature and are widely applied to various mobile devices, for example, smartphones, tablets, laptop computers, or smartwatches. The existing wireless communication chip supports both a wireless local area network (WLAN) technology and a Bluetooth (BT) communication technology, so as to have a WLAN function and a BT communication function. The mobile device may be connected to the Internet through the WLAN function, and the mobile device may communicate with a peripheral device (for example, a BT headset or a BT speaker) through the BT communication function. However, when the mobile device simultaneously executes the WLAN function and the BT communication function, the existing wireless communication chip often has a problem that a WLAN signal and a BT signal interfere with each other. In this case, the wireless communication chip cannot effectively receive at least one of the WLAN signal and the BT signal, so that the mobile device cannot operate normally as a result of poor efficiency and sensitivity.

### SUMMARY

In some embodiments, the wireless communication chip includes a first amplifier stage, a first radio frequency circuit, and a second radio frequency circuit, and the first radio frequency circuit includes a first mixer, a baseband transconductor, a first output stage, and a switch unit. The first amplifier stage is configured to receive and amplify a radio frequency signal. The first radio frequency circuit is configured to support a first wireless transmission technology. The first mixer is electrically connected to an output terminal of the first amplifier stage. The baseband transconductor is electrically connected to an output terminal of the first mixer, and the baseband transconductor has a first input impedance. The first output stage is electrically connected to an output terminal of the baseband transconductor, and the first output stage has a second input impedance. The switch unit is electrically connected between an input terminal of the baseband transconductor and the output terminal of the baseband transconductor. The second radio frequency circuit is configured to support a second wireless transmission technology different from the first wireless transmission technology, and the second radio frequency circuit has a third input impedance. The second radio frequency circuit and the first radio frequency circuit are jointly coupled to the output terminal of the first amplifier stage. An impedance value of the third input impedance is less than an impedance value of the first input impedance, and the impedance value of the third input impedance is greater than an impedance value of the second input impedance.

In some embodiments, the first wireless transmission technology is a wireless local area network (WLAN) technology, and the second wireless transmission technology is a Bluetooth (BT) communication technology.

In some embodiments, the first mixer is configured to receive, when the radio frequency signal includes a WLAN signal, a second oscillation signal and the WLAN signal from the first amplifier stage, and is configured to adjust a frequency of the WLAN signal based on a first oscillation signal. The baseband transconductor is configured to receive and output the WLAN signal when the switch unit is turned off. The first output stage is configured to receive and output the WLAN signal from the first mixer or the WLAN signal from the baseband transconductor.

In some embodiments, the second radio frequency circuit includes a second amplifier stage, a second mixer, and a second output stage. The second amplifier stage is electrically connected to the output terminal of the first amplifier stage, and the second amplifier stage is configured to receive and amplify, when the radio frequency signal includes a BT signal, the BT signal from the first amplifier stage. The second mixer is electrically connected to an output terminal of the second amplifier stage, and the second mixer is configured to receive a second oscillation signal and the BT signal from the second amplifier stage, and adjust a frequency of the BT signal based on the second oscillation signal. The second output stage is electrically connected to an output terminal of the second mixer, and the second output stage is configured to receive and output the BT signal from the second mixer.

In some embodiments, the radio frequency signal includes a BT signal, and the switch unit is always turned on.

In some embodiments, the radio frequency signal includes a WLAN signal, and the switch unit is always turned off.

In some embodiments, the wireless communication chip further includes a first oscillator and a second oscillator. The first oscillator is electrically connected to the first mixer, and the first oscillator is configured to generate a first oscillation signal. The second oscillator is electrically connected to the second mixer, and the second oscillator is configured to generate a second oscillation signal.

In some embodiments, the first radio frequency circuit further includes a variable resistor. The variable resistor is electrically connected between the output terminal of the first amplifier stage and an input terminal of the first mixer, and the impedance value of the third input impedance is related to a resistance value of the variable resistor.

In some embodiments, the third input impedance of the second radio frequency circuit increases in response to an increase in the resistance value of the variable resistor, to reduce a leakage current flowing into the second radio frequency circuit.

In some embodiments, the third input impedance of the second radio frequency circuit decreases in response to a decrease in the resistance value of the variable resistor, to increase a leakage current flowing into the second radio frequency circuit.

In some embodiments, the first radio frequency circuit further includes a capacitor, and the capacitor is electrically connected to the input terminal of the baseband transconductor.

In some embodiments, the wireless communication chip further includes a detector. The detector is electrically connected to an input terminal of the first mixer and a control terminal of the switch unit, and the detector is configured to detect a leakage current and turn on or turn off the switch unit based on the leakage current.

In some embodiments, the first output stage includes a transimpedance amplifier, a baseband circuit, and an analog-to-digital converter. The baseband transconductor, the transimpedance amplifier, the baseband circuit, and the analog-to-digital converter are connected in series in sequence.

In some embodiments, the second output stage includes a transimpedance amplifier, a baseband circuit, and an analog-to-digital converter. The second mixer, the transimpedance amplifier, the baseband circuit, and the analog-to-digital converter are connected in series in sequence.

In summary, according to any embodiment, the wireless communication chip can flexibly adjust an object on which signal improvement is performed. The wireless communication chip can improve efficiency and sensitivity thereof in receiving the BT signal by turning on the switch unit, and does not have significant impact on sensitivity in receiving the WLAN signal. In some embodiments, the wireless communication chip can improve the efficiency and the sensitivity thereof in receiving the WLAN signal by turning off the switch unit and arranging the capacitor. In some embodiments, the wireless communication chip can control the on state of the switch unit based on a value of the leakage current, so that the wireless communication chip can adaptively adjust the efficiency and the sensitivity thereof when executing a WLAN function/a BT communication function, thereby improving performance of the wireless communication chip.

### BRIEF DESCRIPTION OF THE DRAWINGS

FIG. 1 is a schematic diagram of a circuit of an operating manner of a wireless communication chip according to a first embodiment;

FIG. 2 is a schematic diagram of a circuit of another operating manner of the wireless communication chip in FIG. 1;

FIG. 3 is a schematic diagram of a circuit of an operating manner of a wireless communication chip according to a second embodiment;

FIG. 4 is a schematic diagram of a circuit of another operating manner of the wireless communication chip in FIG. 3;

FIG. 5 is a schematic diagram of a circuit of an operating manner of a wireless communication chip according to a third embodiment;

FIG. 6 is a schematic diagram of a circuit of another operating manner of the wireless communication chip in FIG. 5;

FIG. 7 is a schematic diagram of a circuit of an operating manner of a wireless communication chip according to a fourth embodiment;

FIG. 8 is a schematic diagram of a circuit of another operating manner of the wireless communication chip in FIG. 7;

FIG. 9 is a schematic diagram of a circuit of an operating manner of a wireless communication chip according to a fifth embodiment;

FIG. 10 is a schematic diagram of a circuit of another operating manner of the wireless communication chip in FIG. 9;

FIG. 11 is a schematic diagram of an embodiment of a first output stage; and

FIG. 12 is a schematic diagram of an embodiment of a second output stage.

### DETAILED DESCRIPTION

It should be understood for terms used herein that a term “include” is an open term and therefore should be interpreted as “include but not limited to”; terms such as “coupling” or “electrically connecting” means two or more elements being in “directly” physical or electrical contact with each other, or in “indirectly” physical or electrical contact with each other; and terms such as “first”, “second” and “third” are used for distinguishing between referred elements, rather than being used for ranking the referred elements, or limiting differences in the referred elements, or limiting the scope of the present disclosure, unless otherwise specified.

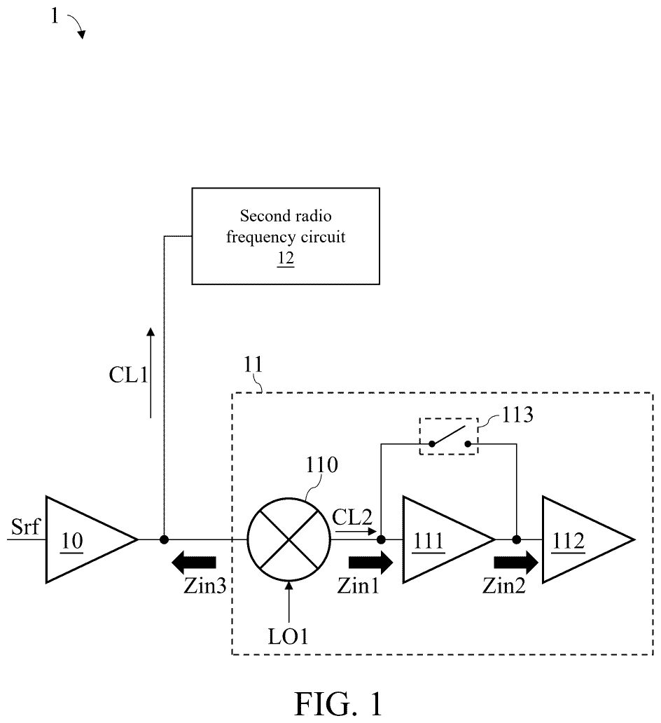

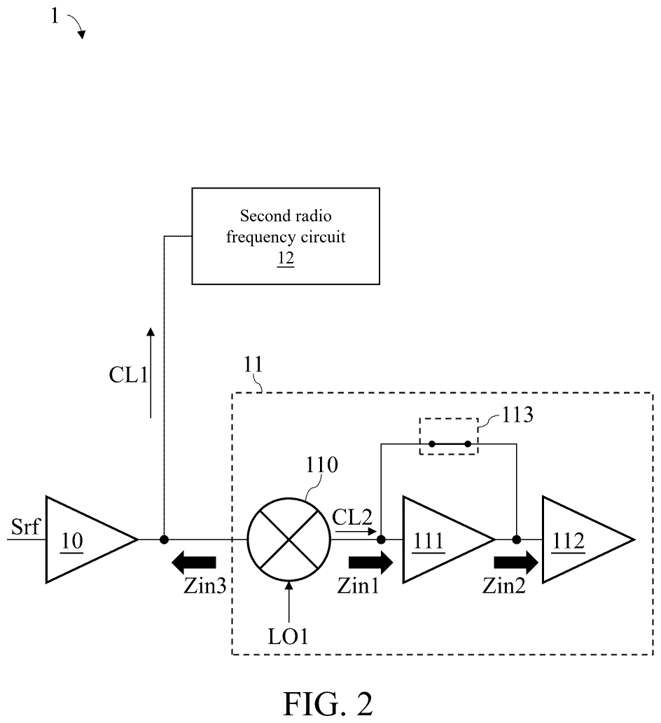

Referring to FIG. 1 to FIG. 2, a wireless communication chip 1 includes an amplifier stage (hereinafter referred to as a first amplifier stage 10) and two radio frequency circuits (hereinafter respectively referred to as a first radio frequency circuit 11 and a second radio frequency circuit 12). The first radio frequency circuit 11 and the second radio frequency circuit 12 are configured to support different wireless transmission technologies. That is, the wireless communication chip 1 has different wireless transmission function. For example, the first radio frequency circuit 11 and the second radio frequency circuit 12 are respectively support a wireless local area network (WLAN) technology and a Bluetooth (BT) communication technology, so that the wireless communication chip 1 has a WLAN function and a BT communication function.

The first radio frequency circuit 11 and the second radio frequency circuit 12 are jointly coupled to an output terminal of the first amplifier stage 10. The first radio frequency circuit 11 includes a mixer (hereinafter referred to as a first mixer 110), a baseband transconductor 111, an output stage (hereinafter referred to as a first output stage 112), and a switch unit 113. The baseband transconductor 111 has an input impedance (hereinafter referred to as a first input impedance Zin1), and the first output stage 112 has another input impedance (hereinafter referred to as a second input impedance Zin2).

In some embodiments, the first mixer 110 is electrically connected to the output terminal of the first amplifier stage 10, the baseband transconductor 111 is electrically connected to an output terminal of the first mixer 110, and the first output stage 112 is electrically connected to an output terminal of the baseband transconductor 111. In other words, in this embodiment, the first mixer 110, the baseband transconductor 111, and the first output stage 112 are connected in series in sequence. The switch unit 113 is electrically connected between an input terminal of the baseband transconductor 111 and the output terminal of the baseband transconductor 111. In other words, in this embodiment, the switch unit 113 is connected in parallel to the baseband transconductor 111.

Referring to FIG. 1 to FIG. 4, in some embodiments, the second radio frequency circuit 12 includes another amplifier stage (hereinafter referred to as a second amplifier stage 120), another mixer (hereinafter referred to as a second mixer 121), and another output stage (hereinafter referred to as the second output stage 122). The second amplifier stage 120 is electrically connected to the output terminal of the first amplifier stage 10, the second mixer 121 is electrically connected to an output terminal of the second amplifier stage 120, and a second output stage 122 is electrically connected to an output terminal of the second mixer 121. In other words, in this embodiment, the second amplifier stage 120, the second mixer 121, and the second output stage 122 are connected in series in sequence. In addition, in some embodiments, the second radio frequency circuit 12 further has an input impedance (hereinafter referred to as a third input impedance Zin3). An impedance value of the third input impedance Zin3 is less than an impedance value of the first input impedance Zin1, and the impedance value of the third input impedance Zin3 is greater than an impedance value of the second input impedance Zin2.

The first radio frequency circuit 11 is configured to support a wireless transmission technology (hereinafter referred to as a first wireless transmission technology), and the second radio frequency circuit 12 configured to support another wireless transmission technology (hereinafter referred to as a second wireless transmission technology). The first wireless transmission technology is different from the second wireless transmission technology. In some embodiments, the first wireless transmission technology is a wireless local area network (WLAN) technology, and the second wireless transmission technology is a Bluetooth (BT) communication technology. Therefore, the wireless communication chip 1 supports both a WLAN function and a BT communication function.

The first amplifier stage 10 is configured to receive and amplify a radio frequency signal Srf. In some embodiments, since the wireless communication chip 1 supports both the WLAN function and the BT communication function, the radio frequency signal Srf received by the first amplifier stage 10 includes at least one of a BT signal and a WLAN signal. To be specific, in this embodiment, the wireless communication chip 1 may receive only at least one of the BT signal and the WLAN signal to execute the corresponding wireless communication function, or may simultaneously receive the BT signal and the WLAN signal to execute both the WLAN function and the BT communication function.

In some embodiments, the wireless communication chip 1 processes the WLAN signal of the radio frequency signal Srf through the first radio frequency circuit 11, thereby achieving the WLAN function. FIG. 1 is used as an example. In this embodiment, when the wireless communication chip 1 executes the WLAN function, the first mixer 110 of the first radio frequency circuit 11 receives an oscillation signal (hereinafter referred to as a first oscillation signal LO1) and the WLAN signal from the first amplifier stage 10, and the first mixer 110 adjusts a frequency of the WLAN signal based on the first oscillation signal LO1. Then the baseband transconductor 111 receives and outputs the WLAN signal from the first mixer 110. Finally, the first output stage 112 receives and outputs the WLAN signal from the baseband transconductor 111, and the first radio frequency circuit 11 transmits the WLAN signal from the first output stage 112 to a device of a next stage (that is, a system, a chip, a circuit, or a module coupled to an output terminal of the first output stage 112). The amplifier stage, the baseband transconductor 111, and the output stage are commonly known to a person of ordinary skill in the art, and therefore details are not described.

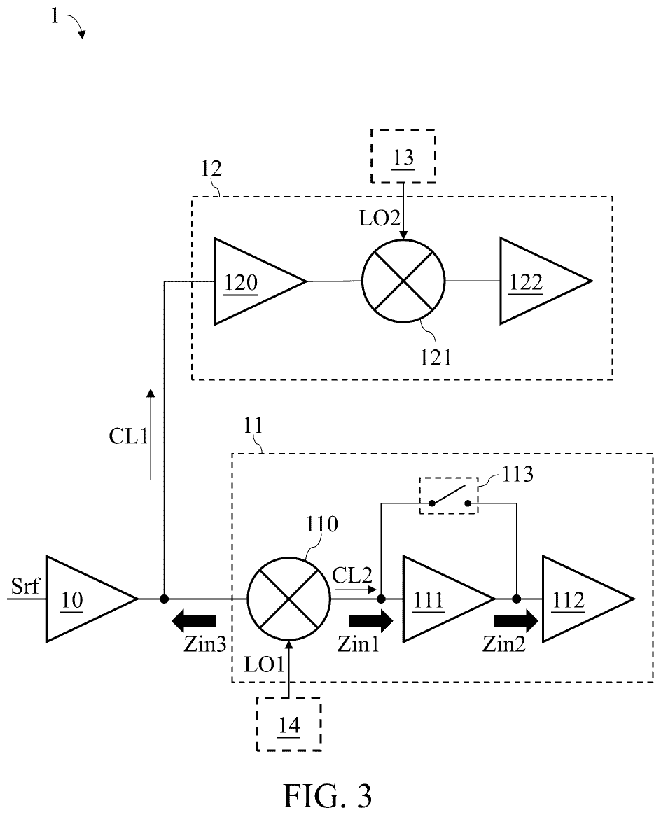

In some embodiments, the wireless communication chip 1 processes the BT signal of the radio frequency signal Srf through the second radio frequency circuit 12, thereby achieving the BT communication function. FIG. 3 is used as an example. In this embodiment, when the wireless communication chip 1 executes the BT communication function, the second amplifier stage 120 receives and amplifies the BT signal from the first amplifier stage 10. Then the second mixer 121 receives another oscillation signal (hereinafter referred to as a second oscillation signal LO2) and the BT signal from the second amplifier stage 120, and the second mixer 121 adjusts a frequency of the BT signal based on the second oscillation signal LO2. Finally, the second output stage 122 receives and outputs the BT signal from the second mixer 121, and the second radio frequency circuit 12 transmits the BT signal from the second output stage 122 to another device of the next stage (that is, a system, a chip, a circuit, or a module coupled to an output terminal of the second output stage 122).

In some embodiments, an on state of the switch unit 113 may be preset based on a circuit state, an application environment, or a combination thereof of the wireless communication chip 1 to improve efficiency and sensitivity of the wireless communication chip 1 during execution of various wireless communication functions.

In some exemplary implementations, FIG. 1 and FIG. 3 are used as examples. The switch unit 113 is set to be always turned off. In this case, when the first mixer 110 receives the first oscillation signal LO1, the first oscillation signal LO1 generates a leakage current CL1 and another leakage current CL2. The leakage current CL1 flows into the second radio frequency circuit 12, the leakage current CL2 flows into the baseband transconductor 111, and a sum of the leakage current CL1 and the leakage current CL2 is a fixed value. Therefore, in response to an input impedance of the second radio frequency circuit 12 (that is, the third input impedance Zin3) being less than an input impedance of the baseband transconductor 111 (that is, the first input impedance Zin1), a value of the leakage current CL1 flowing into the second radio frequency circuit 12 is greater than a value of the leakage current CL2 flowing into the baseband transconductor 111. Therefore, since a current interference borne by the baseband transconductor 111 is less than a current interference borne by the second radio frequency circuit 12 (that is, the value of the leakage current CL2 is less than the value of the leakage current CL1), the efficiency and the sensitivity of the wireless communication chip 1 in executing the WLAN function can be improved.

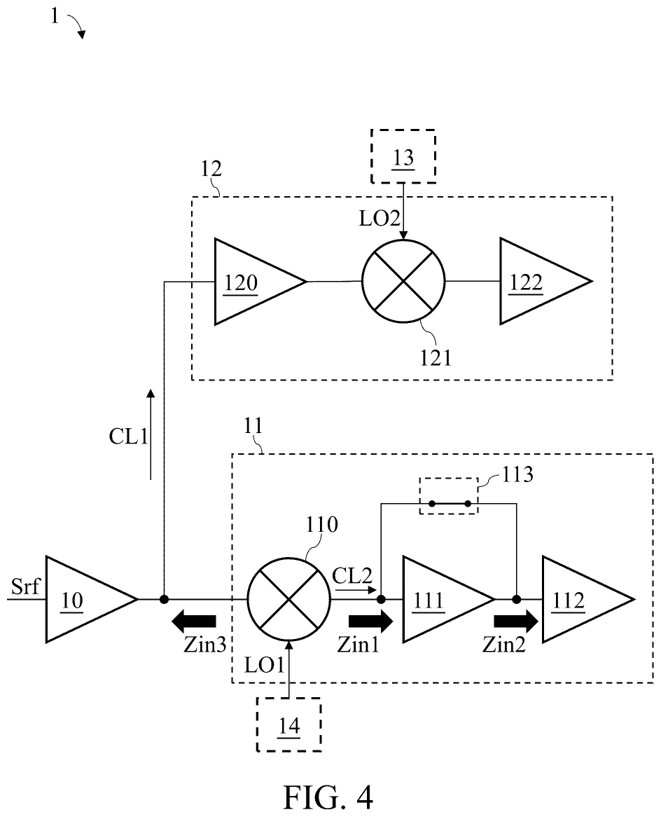

In some other exemplary implementations, FIG. 2 and FIG. 4 are further used as examples. In this embodiment, the switch unit 113 is set to be always turned on. In a case that the switch unit 113 is always turned on, the first output stage 112 receives and amplifies the WLAN signal from the first mixer 110 through the switch unit 113. In other words, the baseband transconductor 111 is short circuited due to the series-connected switch unit 113. In this case, in response to the input impedance of the second radio frequency circuit 12 (that is, the third input impedance Zin3) being greater than an input impedance of the first output stage 112 (that is, the second input impedance Zin2), the value of the leakage current CL1 flowing into the second radio frequency circuit 12 is less than the value of the leakage current CL2 flowing into the first output stage 112. Therefore, compared to the current interference borne by the second radio frequency circuit 12 being less than the current interference borne by the first output stage 112 (that is, the value of the leakage current CL1 is less than the value of the leakage current CL2) when the switch unit 113 is turned off, the efficiency and the sensitivity of the wireless communication chip 1 in executing the BT communication function can be improved. To be specific, the wireless communication chip 1 does not reduce the leakage current CL1 flowing into the second radio frequency circuit 12 by increasing an attenuation, and instead, reduces the leakage current CL1 flowing into the second radio frequency circuit 12 through a pure impedance effect. Therefore, even if the switch unit 113 is turned off, sensitivity of the first radio frequency circuit 11 is not significantly affected.

As shown in FIG. 3 and FIG. 4, in some embodiments, the wireless communication chip 1 further includes two oscillators (hereinafter respectively referred to as a first oscillator 13 and a second oscillator 14). The first oscillator 13 is electrically connected to the first mixer 121, and the second oscillator 14 is electrically connected to the second mixer 110. In some embodiments, the first oscillator 13 is configured to generate the first oscillation signal LO1, and the second oscillator 14 is configured to generate the second oscillation signal LO2. The oscillator is commonly known to a person of ordinary skill in the art, and therefore details are not described.

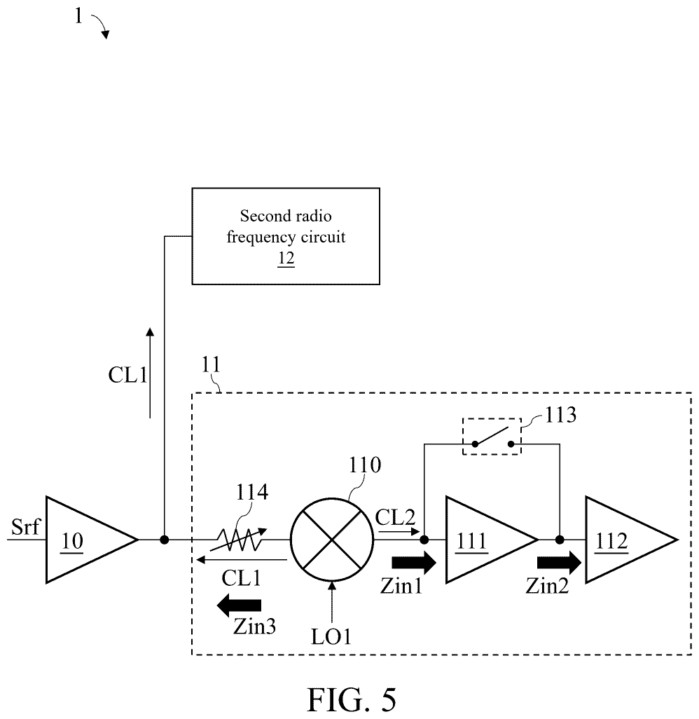

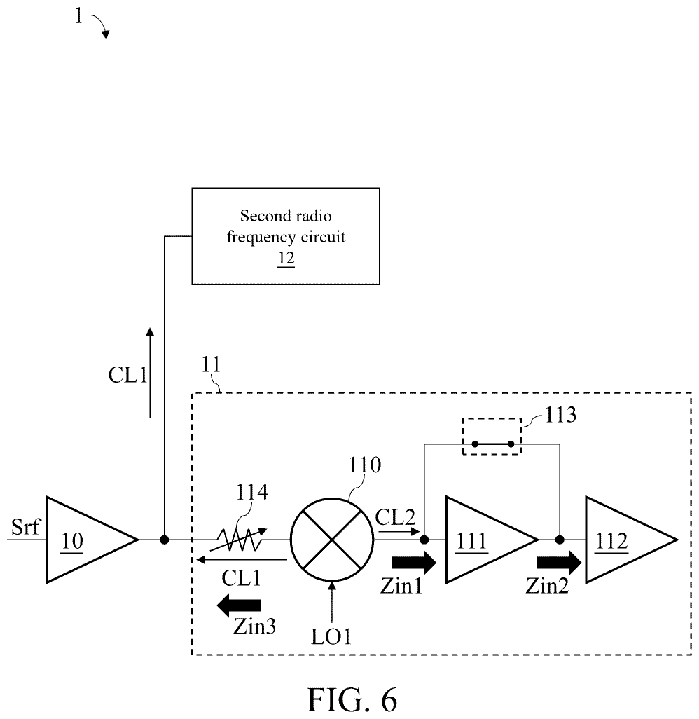

Referring to FIG. 5 and FIG. 6, in some embodiments, a first radio frequency circuit 11 further includes a variable resistor 114, and the variable resistor 114 is electrically connected between an output terminal of a first amplifier stage 10 and an input terminal of a first mixer 110. In some embodiments, the variable resistor 114 is configured to adjust an input impedance of a second radio frequency circuit 12 (that is, a third input impedance Zin3). In other words, in this embodiment, an impedance value of the third input impedance Zin3 is related to a resistance value of the variable resistor 114. In some embodiments, the third input impedance Zin3 of the second radio frequency circuit 12 increases in response to an increase in the resistance value of the variable resistor 114, to reduce a leakage current CL1 flowing into the second radio frequency circuit 12. The third input impedance Zin3 of the second radio frequency circuit 12 decreases in response to a decrease in the resistance value of the variable resistor 114, to increase the leakage current CL1 flowing into the second radio frequency circuit 12. Therefore, through the adjustment of the resistance value of the variable resistor 114, efficiency and sensitivity of the wireless communication chip 1 during execution of various wireless communication functions is further improved.

FIG. 5 is used as an example. In this embodiment, a switch unit 113 is turned off, so that efficiency and sensitivity of the wireless communication chip 1 during execution of a WLAN function are relatively desirable. In this case, the wireless communication chip 1 may reduce the resistance value of the variable resistor 114, to reduce a value of a leakage current CL2, thereby further improving the efficiency and the sensitivity of the wireless communication chip 1 during the execution of the WLAN function. FIG. 6 is still used as an example. In this embodiment, a switch unit 113 is turned on, so that efficiency and sensitivity of the wireless communication chip 1 during execution of a BT function are relatively desirable. In this case, the wireless communication chip 1 may increase the resistance value of the variable resistor 114, to reduce a value of the leakage current CL1, thereby further improving the efficiency and the sensitivity of the wireless communication chip 1 during the execution of the BT communication function.

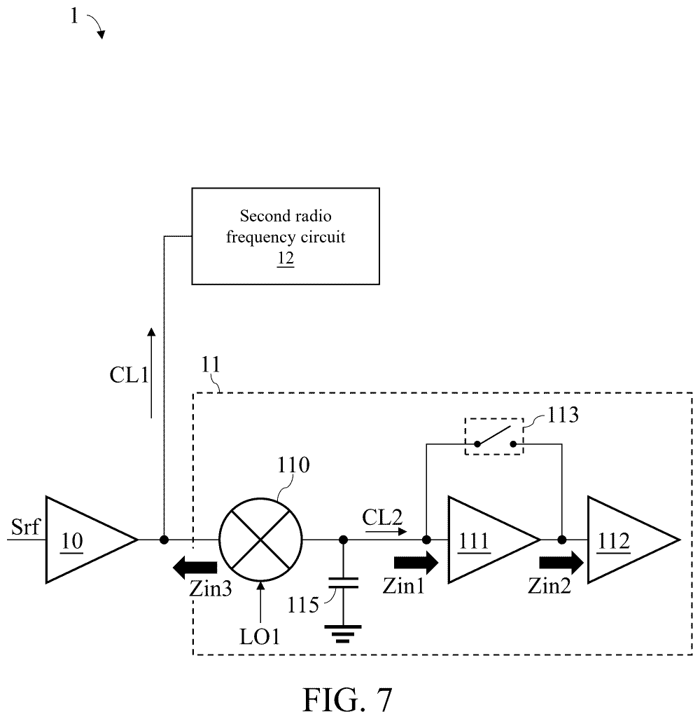

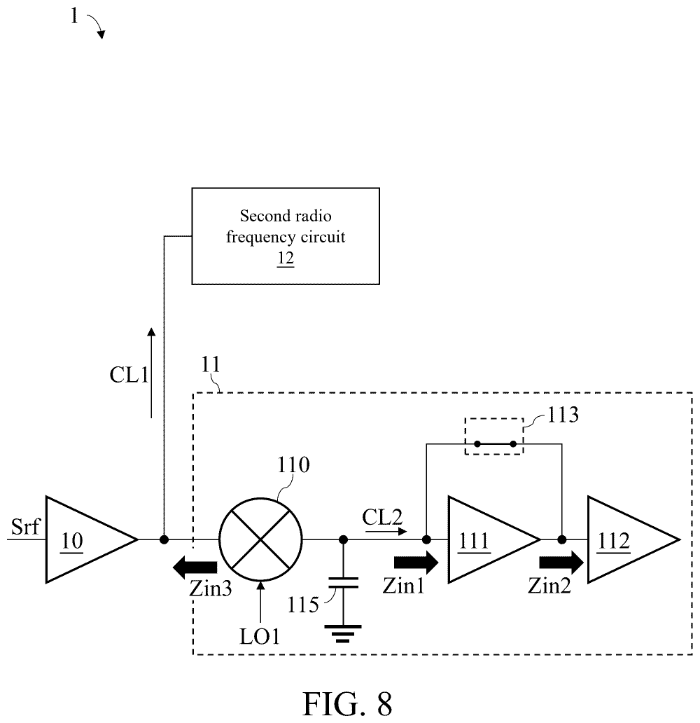

Referring to FIG. 7 and FIG. 8, in some embodiments, a first radio frequency circuit 11 further includes a capacitor 115. An end of the capacitor 115 is electrically connected to an input terminal of a baseband transconductor 111, and an other end of the capacitor 115 is grounded. In some embodiments, the capacitor 115 and an input impedance of the baseband transconductor 111 (that is, a first input impedance Zin1) or an input impedance of the first output stage 112 (that is, a second input impedance Zin2) forms a resistor-capacitor (RC) circuit, to eliminate an out-of-band interference in a WLAN signal (for example, to eliminate a high-frequency signal in the WLAN signal), thereby improving signal integrity (SI) of the received WLAN signal. The RC circuit is commonly known to a person of ordinary skill in the art, and therefore details are not described.

In some embodiments, since the first input impedance Zin1 is greater than the second input impedance Zin2, an equivalent impedance of an output terminal of a first mixer 110 (that is, the first input impedance Zin1) is a high impedance when the switch unit 113 is turned off, so that the wireless communication chip 1 can effectively improve the elimination effect on the high-frequency signal.

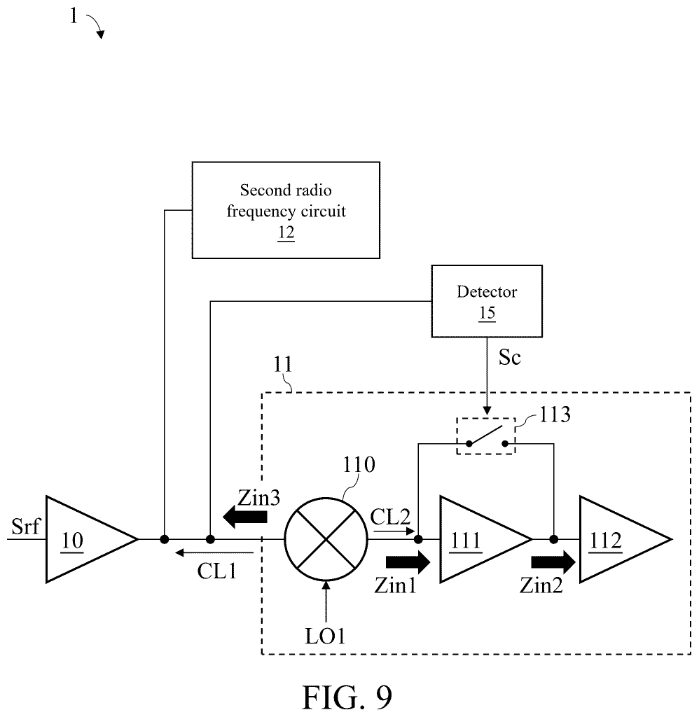

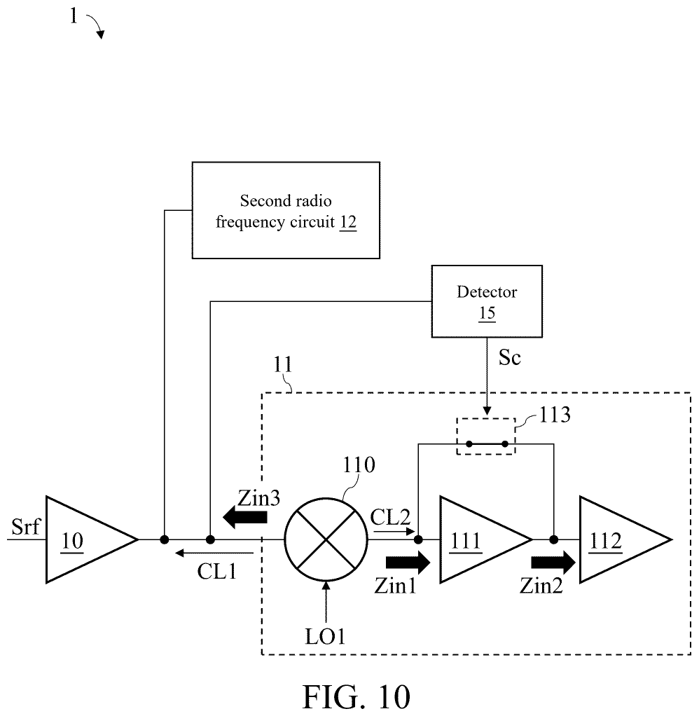

Referring to FIG. 9 and FIG. 10, in some embodiments, an on state of a switch unit 113 may be dynamically adjusted based on a state of a signal. Specifically, a wireless communication chip 1 may further include a detector 15, and the detector 15 is electrically connected to an input terminal of a first mixer 110 and a control terminal of the switch unit 113. In some embodiments, the detector 15 is configured to detect a leakage current CL1 and turn on or turn off the switch unit 113 based on the leakage current CL1 (as shown in FIG. 9 and FIG. 10). In some other embodiments, the detector 15 is configured to detect a leakage current CL2 and turn on or turn the switch unit 113 (not shown in the figure) based on the leakage current CL2. FIG. 9 and FIG. 10 are used as examples. When a value of the leakage current CL1 is greater than a threshold, it represents that a current interference borne by a second radio frequency circuit 12 is greater than a current interference borne by a first radio frequency circuit 11. In this case, the detector 15 generates a corresponding control signal Sc (for example, but not limited to, a high-voltage level signal) to turn on the switch unit 113, thereby reducing the current interference borne by the second radio frequency circuit 12. When the value of the leakage current CL1 is less than or equal to the threshold, it represents that the current interference borne by the first amplifier stage 10 is greater than the current interference borne by the second radio frequency circuit 12. In this case, the detector 15 generates another corresponding control signal Sc (for example, but not limited to, a low-voltage level signal) to turn off the switch unit 113, thereby reducing the current interference borne by the first amplifier stage 10. Therefore, the wireless communication chip 1 can adaptively turn on/off the switch unit 113 through the detector 15, to reduce the current interference borne by the second radio frequency circuit 12/the first amplifier stage 10.

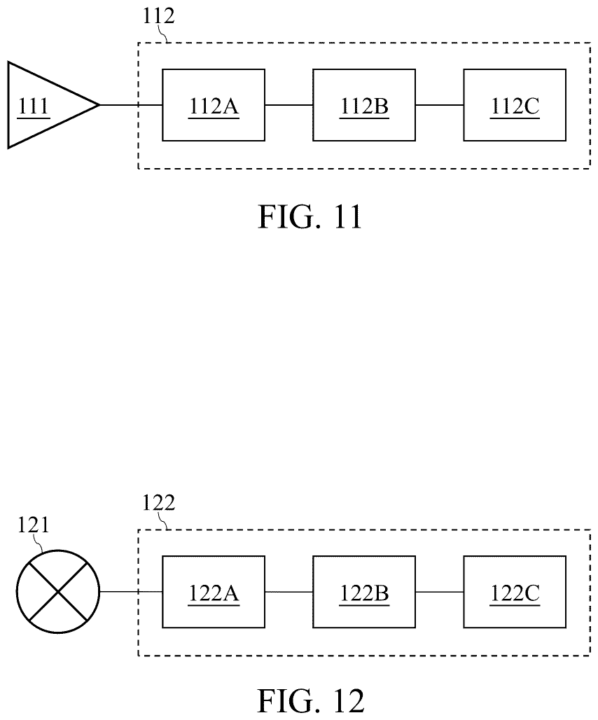

Referring to FIG. 11 and FIG. 12, in some embodiments, a first output stage 112 includes a transimpedance amplifier 112A, a baseband circuit 112B, and an analog-to-digital converter 112C (as shown in FIG. 11). A baseband transconductor 111, the transimpedance amplifier 112A, the baseband circuit 112B, and the analog-to-digital converter 112C are connected in series in sequence. In some embodiments, a second output stage 122 includes a transimpedance amplifier 122A, a baseband circuit 122B, and an analog-to-digital converter 122C (as shown in FIG. 12). A second mixer 121, the transimpedance amplifier 122A, the baseband circuit 122B, and the analog-to-digital converter 122C are connected in series in sequence. In some embodiments, the transimpedance amplifiers 112A and 122A are configured to amplify a current signal and convert the current signal into a voltage signal. In some embodiments, the baseband circuits 112B and 122B are configured to eliminate an out-of-band signal of the voltage signal, to preserve a voltage signal with relatively high signal integrity (for example, but not limited to, a signal with a frequency of 2.4 GHZ). In some embodiments, the analog-to-digital converters 112C and 122C are configured to convert the voltage signal to a digital signal from an analog signal. Therefore, the wireless communication chip 1 may provide a WLAN signal to a device of a next stage through a first amplifier stage 10, and the wireless communication chip 1 may provide a BT signal to another device of the next stage through a second amplifier stage 120. The transimpedance amplifiers 112A and 122A, the baseband circuits 112B and 122B, and the analog-to-digital converters 112C and 122C are commonly known to a person of ordinary skill in the art, and therefore details are not described.

In some embodiments, each of the first amplifier stage 10 and the second amplifier stage 120 may be a single amplifier with a signal amplification function, or a circuit with the signal amplification function including a plurality of amplifiers. The amplifier may be, for example, but not limited to, an electronic amplifier, a power amplifier, a transistor amplifier, or an operation amplifier.

In some embodiments, the switch unit 113 may be a hardware element with a switch function, or may be a semiconductor element configured to achieve a switching function, for example, but is not limited to, a transmission gate, a switch diode, a bipolar junction transistor (BJT), and a metal oxide semiconductor field-effect transistor (MOSFET).

In summary, according to any embodiment, the wireless communication chip can flexibly adjust an object on which signal improvement is performed. The wireless communication chip can improve the efficiency and the sensitivity thereof in receiving the BT signal by turning on the switch unit, and does not have significant impact on sensitivity in receiving the WLAN signal. In some embodiments, the wireless communication chip can improve the efficiency and the sensitivity thereof in receiving the WLAN signal by turning off the switch unit and arranging the capacitor. In some embodiments, the wireless communication chip can control the on state of the switch unit based on the value of the leakage current, so that the wireless communication chip can adaptively adjust the efficiency and the sensitivity thereof when executing the WLAN function/the BT communication function, thereby improving performance of the wireless communication chip.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A wireless communication chip, comprising:
a first amplifier stage, configured to receive and amplify a radio frequency signal;
a first radio frequency circuit, configured to support a first wireless transmission technology, wherein the first radio frequency circuit comprises:
a first mixer, electrically connected to an output terminal of the first amplifier stage;
a baseband transconductor, electrically connected to an output terminal of the first mixer, and having a first input impedance;
a first output stage, electrically connected to an output terminal of the baseband transconductor, and having a second input impedance; and
a switch unit, electrically connected between an input terminal of the baseband transconductor and the output terminal of the baseband transconductor; and
a second radio frequency circuit, configured to support a second wireless transmission technology different from the first wireless transmission technology, wherein the second radio frequency circuit has a third input impedance, and the second radio frequency circuit and the first radio frequency circuit are jointly coupled to the output terminal of the first amplifier stage; and
an impedance value of the third input impedance is less than an impedance value of the first input impedance, and the impedance value of the third input impedance is greater than an impedance value of the second input impedance.

2. The wireless communication chip according to claim 1, wherein the first wireless transmission technology is a wireless local area network (WLAN) technology, and the second wireless transmission technology is a Bluetooth (BT) communication technology.

3. The wireless communication chip according to claim 1, wherein the first mixer is configured to receive, when the radio frequency signal comprises a WLAN signal, a second oscillation signal and the WLAN signal from the first amplifier stage, and is configured to adjust a frequency of the WLAN signal based on a first oscillation signal;
the baseband transconductor is configured to receive and output the WLAN signal when the switch unit is turned off; and
the first output stage is configured to receive and output the WLAN signal from the first mixer or the WLAN signal from the baseband transconductor.

4. The wireless communication chip according to claim 1, wherein the second radio frequency circuit comprises:
a second amplifier stage, electrically connected to the output terminal of the first amplifier stage, and configured to receive and amplify, when the radio frequency signal comprises a BT signal, the BT signal from the first amplifier stage;
a second mixer, electrically connected to an output terminal of the second amplifier stage, and configured to receive a second oscillation signal and the BT signal from the second amplifier stage, and adjust a frequency of the BT signal based on the second oscillation signal; and
a second output stage, electrically connected to an output terminal of the second mixer, and configured to receive and output the BT signal from the second mixer.

5. The wireless communication chip according to claim 1, wherein the radio frequency signal comprises a BT signal, and the switch unit is always turned on.

6. The wireless communication chip according to claim 1, wherein the radio frequency signal comprises a WLAN signal, and the switch unit is always turned off.

7. The wireless communication chip according to claim 1, further comprising:
a first oscillator, electrically connected to the first mixer, and configured to generate a first oscillation signal; and
a second oscillator, electrically connected to the second radio frequency circuit, and configured to generate a second oscillation signal.

8. The wireless communication chip according to claim 1, wherein the first radio frequency circuit further comprises a variable resistor, the variable resistor is electrically connected between the output terminal of the first amplifier stage and an input terminal of the first mixer, and the impedance value of the third input impedance is related to a resistance value of the variable resistor.

9. The wireless communication chip according to claim 8, wherein the third input impedance of the second radio frequency circuit increases in response to an increase in the resistance value of the variable resistor, to reduce a leakage current flowing into the second radio frequency circuit.

10. The wireless communication chip according to claim 8, wherein the third input impedance of the second radio frequency circuit decreases in response to a decrease in the resistance value of the variable resistor, to increase a leakage current flowing into the second radio frequency circuit.

11. The wireless communication chip according to claim 1, wherein the first radio frequency circuit further comprises a capacitor, and the capacitor is electrically connected to the input terminal of the baseband transconductor.

12. The wireless communication chip according to claim 1, further comprising a detector, wherein the detector is electrically connected to an input terminal of the first mixer and a control terminal of the switch unit, and the detector is configured to detect a leakage current and turn on or turn off the switch unit based on the leakage current.

13. The wireless communication chip according to claim 1, wherein the first output stage comprises:
a transimpedance amplifier;
a baseband circuit; and
an analog-to-digital converter, wherein the baseband transconductor, the transimpedance amplifier, the baseband circuit, and the analog-to-digital converter are connected in series in sequence.

14. The wireless communication chip according to claim 4, wherein the second output stage comprises:
a transimpedance amplifier;
a baseband circuit; and
an analog-to-digital converter, wherein the second mixer, the transimpedance amplifier, the baseband circuit and the analog-to-digital converter are connected in series in sequence.
